(19) United States
(12) Patent Application Publication
(10) Pub. No.: US 2002/0063599 A1
(43) Pub. Date: May 30, 2002

(54) Efficient all NPN high output class AB output stage with latchup free boosting scheme

(76) Inventors: Priscilla Escobar-Bowser, Plano, TX (US); Marco Corst, Parker, TX (US)

Correspondence Address: TEXAS INSTRUMENTS INCORPORATED, P O BOX 655474, M/S 3999, DALLAS, TX, 75265

(21) Appl. No.: 09/725,579

(22) Filed: Nov. 29, 2000

Related U.S. Application Data
(60) Provisional application No. 60/171,347, filed on Dec. 21, 1999.

(51) Int. Cl. H03F 3/26

(52) U.S. Cl. 330/274

(57) ABSTRACT

A Class AB amplifier (10) having a top booster section (14) and a bottom booster section (12) adapted to prevent crossover distortion, latchup, and provides high output voltage swing output. The amplifier 10 has a positive feedback loop including a current mirror comprising transistors (M1, M2) that get activated during extreme sourcing conditions. The feedback loop provides the necessary biasing current to a biasing transistor (Q9) of an output sinking transistor (Q11) to allow high output sourcing current and high sinking current to prevent crossover distortion and latching. The output transistors (Q8, Q9, Q10 and Q11) of the amplifier (10) are all NPN-type transistors.

### FIELD OF THE INVENTION

The present invention is related to amplifiers circuits, and more particularly to Class AB amplifier circuits.

### BACKGROUND OF THE INVENTION

There are a variety of amplifiers circuits available to a circuit designer, with some of the widely known types being Class A, Class B and Class AB amplifiers. It is widely known that Class A amplifiers have high fidelity but have poor efficiency. Class B amplifiers are known to have high efficiency, but poor fidelity. Class AB output stages attempt to achieve a compromise between the two. Class AB amplifiers have a relatively high efficiency by quiescently biasing the amplifier with substantial current, enough to drive it up to a given low impedance load where the amplifier has a Class A operation. As the load impedance gets lower the Class AB amplifier starts diverting some portion of the quiescent current towards the base of the output transistors, thus unwantedly debiasing the critical circuitry driving the output transistors. At this point the amplifier is purely a Class B amplifier, whereby cross-over distortion is inevitable. At this point, the fidelity of the amplified signal rapidly degrades.

The traditional Class AB bipolar junction transistor (BJT) output stage has the characteristics of very low quiescent power consumption with no resistive load, and a significantly larger sinking and sourcing current driving capability with a low impedance load. The traditional way that this is achieved is by quiescently biasing the amplifier in such a way that if a low impedance load is applied to the output, current once utilized to quiescently bias the amplifier is then re-diverted towards the base of the amplifier's output transistors, while the rest of the amplifier is left with enough current to maintain its critical circuitry “on”. However, if there is not enough quiescent current leftover when driving the given low impedance load, the critical circuitry in the amplifier will be “starved” in the effort to drive the given load, thus undesirably driving the transistors of the amplifiers critical circuitry into “cut off”. This exacerbates the effort that the amplifier has to do to bring the transistors back “on”, biased and ready for the next amplifier output transition. This results in crossover distortion due to the “off” time of those output transistors involved. This will be the case for both the rising and falling output transitions of the amplifier. For the existing approaches, amplifiers are specified to drive a minimum impedance load with a given crossover distortion, subjecting the amplifier to higher quiescent currents when lower impedance loads are required to be driven. Applying loads beyond these minimum impedance low limits will result in the considerable crossover distortion already mentioned.

Another problem is that amplifiers having all NPN output stages are limited in output drive, which drive is based upon the amount of quiescent current that the designer establishes and accepts for the all NPN output stage, i.e., the amount of nominal current the circuit draws in a no load situation.

There is desired an improved Class AB amplifier that has a fast and stable feedback mechanism to maintain its critical circuitry “on” during both sinking and sourcing conditions, and also which can achieve higher output currents with nominal quiescent current without the risk of circuit latchup.

### SUMMARY OF THE INVENTION

The present invention achieves technical advantages as a power efficient, all NPN, high output voltage swing Class AB output stage with self current compensation to critical circuitry for unlimited sinking and sourcing drive capability, while maintaining a crossover distortion free amplifier, this circuit achieving higher output currents with nominal quiescent current without the risk of circuit latchup. As a result, the architecture maintains high efficiency and high fidelity for almost any resistive load by keeping all the amplifier's critical circuitry “on”, independent of the load. The present invention provides a negative feedback, self-regenerative bias current OP Amp for sinking and sourcing modes, thereby providing unlimited driving capability, with improved circuitry to achieve nominal quiescent current without circuit latchup.

In a first embodiment of the present invention, there is provided an all NPN output stage Class AB amplifier including a first current mirror providing additional positive feedback to the output transistors such that when the output transitions from a sourcing mode to a sinking mode, the critical output circuitry will remain “on” to prevent the output signal from crossover distortion, thus maintaining high fidelity.

In a second embodiment of the present invention, there is provided additional circuitry in an all NPN output stage, allowing higher output currents to be provided in the sinking mode with a nominal quiescent current, the additional circuitry preventing latchup of the critical output circuitry while providing an improved current boosting scheme.

### BRIEF DESCRIPTION OF THE DRAWINGS

FIG. 1 is a schematic drawing of a preferred embodiment of the invention depicting a Class AB amplifier having an improved bottom booster section preventing crossover distortion in a sinking mode, and having an improved top booster section providing current boosting and preventing latchup; and

FIG. 2 is a schematic diagram of an alternative Class AB output stage subject to latchup.

### DESCRIPTION OF THE PREFERRED EMBODIMENT

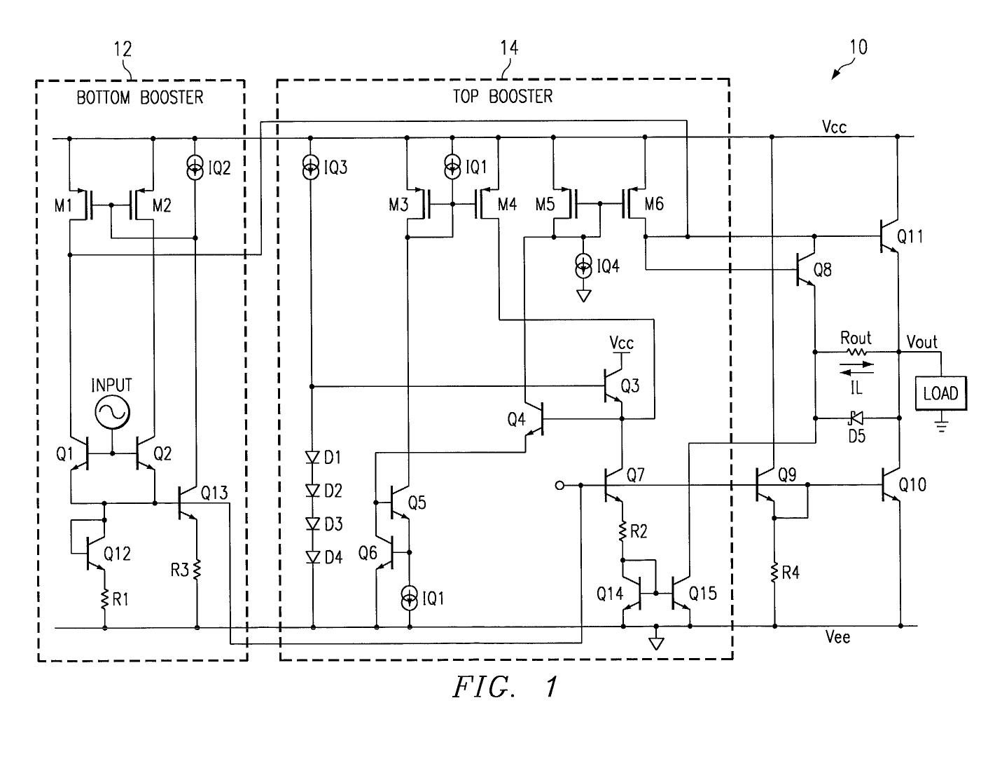

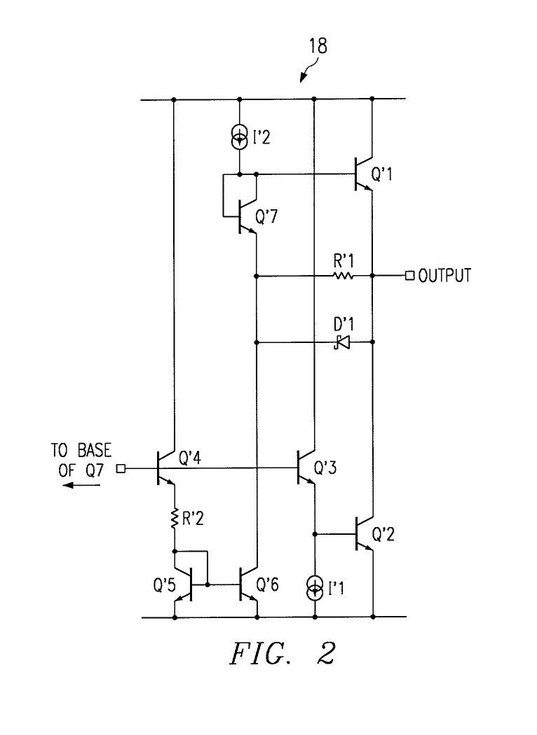

Referring now to FIG. 1, there is depicted a Class AB amplifier 10 having a bottom booster section 12 and an upper booster section 14. The bottom booster 12 is composed of transistors M1, M2, Q1, Q2, Q12 and Q13, and emitter degeneration resistors R1 and R3. The top booster 14 consists of transistors M3, M4, Q3, Q4, Q5, Q6, Q7, emitter degeneration resistor R2, and diodes D1, D2, D3 and D4. Amplifier 10 has output transistors Q10 and Q11. Transistors Q8 and Q9 set the quiescent current to the amplifier's output transistors Q10 and Q11. The current sources IQ1, IQ2, IQ3 and IQ4 set the quiescent current and the thresholds at which the top and bottom booster start operating. The amplifier's input signal is presented at the base of transistors Q1 and Q2. The bottom booster 12 will be described in detail first, and followed by a detailed description of the upper booster 14.

Referring first to bottom booster 12, the bottom booster 12 comprises a current mirror formed by transistors Q1 and Q2, a current mirror formed by M1 and M2, a diode connected transistor Q12 with an emitter degeneration resistor R1, transistor Q13 and an emitter degeneration resistor R3. Transistor Q12 and emitter degeneration resistor RI set the quiescent current in transistors Q1 and Q2. The current of transistor Q2 is initially provided by the current source IQ2. Current source IQ2 also provides the quiescent current to transistor Q13. The current conducted through transistor Q1 is initially provided by a current mirror formed by PMOS transistors M5 and M6, and is quiescently set by current IQ4 and the collector current through transistor Q4. This current is set by the translinear loop formed by diodes D1, D2, D3 and D4, and transistors Q3, Q4, Q5 and Q6. A portion of the current from the PMOS transistors M5 and M6 mirror is diverted towards transistors Q8 and Q9 to provide the quiescent biasing to the output transistors Q10 and Q11. Also, the collector current in transistor Q4 is set to be very low during both quiescent and sinking conditions.

Bottom booster 12 operates as follows. When the output voltage at output Vₒᵤₜ transitions from high to low, depending on the amplifier's output load, the bottom output transistor Q11 has to be able to pull current IL (Vout/Rload) out of the output load down to the VEE rail, assuming that the amplifier's load is to ground and the amplifier 10 has split power supplies with respect to ground. The current that transistor Q11 pulls down will be limited in the first place by the current available to drive it's base, and secondly by the base current provided to transistors Q1 and Q2. Notice that transistors Q1 and Q2 and output transistor Q1 form a Darlington pair such that the output current sinking capability of amplifier 10 will be at least the base current provided to transistor Q1 times hfe (Q1) times hfe (Q11). This second limitation is not significant, given that it is at least three orders of magnitude smaller than the output sinking capability of the amplifier 10 via transistor Q11, assuming the hfes of these transistors to be about 30. Notice, also, that quiescently there is an insignificant amount of base current provided to transistor Q11. This current comes from transistors Q1 and Q2, and it is set mostly by the current sources IQ2 and IQ4.

Now, when there is a low impedance load at the amplifier's output Vₒᵤₜ, and the output is transitioning from sourcing into sinking mode, initially transistor Q2 will get current from the current source IQ2. Once the current needed by Q2 exceeds IQ2, the PMOS transistor M2 will provide the extra needed current. This amount of extra current will then get mirrored onto transistor M1 and will be fed back into transistor Q1, preventing it's saturation and thus providing the extra current needed to drive the output transistor Q1.

Notice that the current through the rest of the amplifier 10 has not changed from what it is quiescently set as. So, as a result of this, so far the output sourcing transistor Q10 and it's biasing diode have not changed from the quiescent operating point, thus maintaining the amplifier's critical circuitry “on.” Notice though, that in order to prevent biasing transistor Q9 from saturating during sinking conditions, current needs to be supplied to transistor Q9 whenever it needs it.

In the prior art Class AB amplifiers, this current would typically come from the output load through resistor Rout. This current builds a DC voltage drop across resistor Rout that then gets imposed on the transistor Q10 base-emitter junction, so that for extreme sinking conditions, the DC voltage drop across resistor Rout will eventually reverse bias the transistor Q10 base-emitter junction, and turn output transistor Q10 “off.” This, if not prevented, will cause the output signal to have cross over distortion, thus rapidly degrading the fidelity of the amplifier's output signal.

Advantageously, according to the present invention, in order to prevent cutoff of output transistor Q10, the transistor Q13 and its emitter degeneration resistor R3 mirror the current in biasing transistor Q9. Notice that this extra current will be provided by transistor M2, which current will mirror into transistor M1 that will replace current back to biasing transistor Q9 through transistor Q8. Notice also that even though the current will increase through transistor Q8, the emitter degeneration resistor R4 of transistor Q9 keeps this current relatively small when compared with transistor Q11 current. Also, due to the 1 to 10 ratioing, the current through output transistor Q10 stays very small overall. The benefit of this topology, when compared with others available, is that it provides not just base current to the output transistors Q10 and Q11, but also rebiases the critical circuitry of the amplifier 10 such that cross over distortion is fully prevented.

Advantageously, when this bottom booster 12 is combined with the top booster 14, that basically has the same function of this bottom booster, but gets activated during the sourcing condition, there is achieved a Class AB amplifier having almost infinite driving capability during both sinking and sourcing conditions, and extremely high fidelity typical of the Class A amplifier with a very minimal quiescent current, typical of the Class AB amplifier.

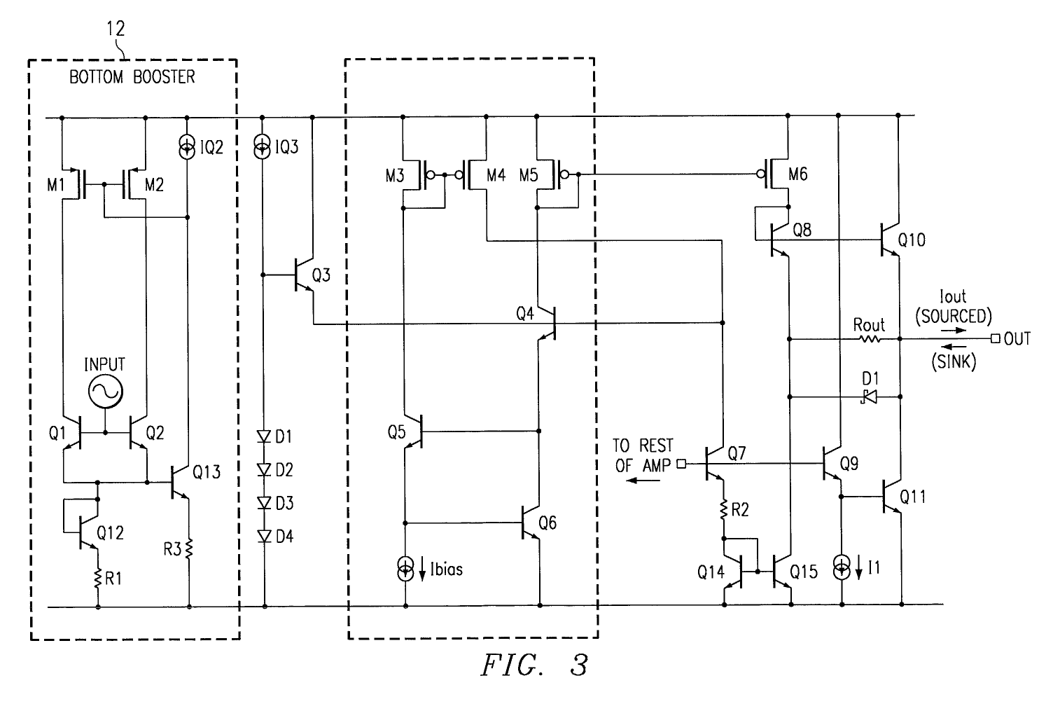

Referring now to FIG. 2, there is shown an alternative top booster at 18 which will be described first. Transistors Q4′, Q5′, Q6′, Q3′ and Q2′ form the quiescent current control loop for low amounts of current sunk into load, R2′ has a small effect, and the quiescent current of the output is controlled by current I2′ and the emitter area ratios of transistors Q2′, Q3′, Q4′, Q5′ and Q6′.

When sinking large currents, a voltage develops across resistor R2′allowing the current in transistor Q2′ to increase faster than the current in transistor Q6′, this maintains bias current in the highside NPN transistor Q1′ which in turn leads to low crossover distortion and good linearity.

When sourcing current, transistor Q2′ starts to turn off, along with transistors Q3′, Q4′, Q5′, Q6′, this allows more of current I2′ to flow into the base of transistor Q1′.

On the limit, when transistor Q2′, Q3′, Q4′, Q5′ and Q6′ are off, all of current 12′ flows into the base of transistor Q1′ and the output can no longer source additional current. At low temperatures or for low values of beta, current I2′ will need to be quite large if the output stage is needed to deliver large amounts of high-side output current.

Referring now back to FIG. 1 top booster 14 provides an advantageous boosting scheme. Transistors M3 and M4 form one current mirror, and transistors M5 and M6 form another.

Transistors Q5, Q6, M3, M4 and Q4 form a simple positive feedback loop. Transistor Q5 measures the base current in transistor Q6, and then mirrors this current back round to the base of transistor Q4, essentially squaring the beta (β) of transistor Q4 with the addition of some positive feedback.

IM4=IQ1+IQ4/Iβ

This means that the current in transistor M4 adjusts itself to ensure that it is equal to the base current of transistor Q4 plus current IQ1. Any surplus current is sunk into transistor Q7.

Since transistor Q7 can sink away any surplus current, the circuit 10 can not latch. So, now the current of transistor M3 adjusts itself to provide for the base current of output transistor Q11 allowing the output stage to source much more current than it previously could. Transistor Q3, and diodes D1, D2, D3 and D4 prevent transistor Q7 from saturating when sinking large amounts of current.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

WE claim:

1. An amplifier coupable to a load, comprising:
a Class AB output stage having a first output transistor coupled to a second output transistor with an amplifier output defined therebetween; and
feedback circuitry coupled to said second output transistor and providing feedback preventing crossover distortion at said amplifier output when said second output transistor sinks current from the load.

2. The amplifier as specified in claim 1 wherein said feedback circuitry comprises a current mirror.

3. The amplifier as specified in claim 2 wherein said current mirror provides additional biasing current to said second transistor when said second output transistor sinks current exceeding a predetermined limit from the load.

4. The amplifier as specified in claim 3 wherein said current mirror provides a biasing current to said first transistor that is substantially smaller than the biasing current to said second transistor.

5. The amplifier as specified in claim 1 wherein said first transistor conducts current when sourcing current to the load, and the second transistor conducts current when sinking current from the load.

6. The amplifier as specified in claim 1 further comprising a first biasing transistor coupled to said first output transistor, a second biasing transistor coupled to said second output transistor, wherein said feedback is provided to said second biasing transistor.

7. The amplifier as specified in claim 1 wherein said feedback is positive feedback.

8. The amplifier as specified in claim 1 wherein all said transistors are comprised of NPN type bipolar transistors.

9. The amplifier as specified in claim 1 wherein said feedback circuitry is adapted to also prevent said second transistor from latching.

10. An amplifier couplable to a load, comprising:
a Class AB output stage having a first output transistor and a second output transistor coupled to said first output transistor with an amplifier output defined therebetween; and
feedback circuitry coupled to said second output transistor providing feedback such that said second transistor can not latch.

11. The amplifier as specified in claim 10 wherein said feedback circuitry sinks biasing current exceeding a predetermined threshold from said second transistor.

12. The amplifier as specified in claim 11 wherein said second transistor sinks current from the load.

13. The amplifier as specified in claim 12 wherein said feedback circuitry comprises a current mirror.

14. The amplifier as specified in claim 13 wherein said current mirror provides positive said feedback.

15. The amplifier as specified in claim 13 wherein said current mirror adjusts biasing current provided to said first and second output transistor as a function of the magnitude of sourcing/sinking current to/from, respectively, the load.

16. The amplifier as specified in claim 10 further comprising a first biasing transistor coupled to said first output transistor, and a second biasing transistor coupled to said second output transistor.

17. The amplifier as specified in claim 16 wherein said current mirror adjusts biasing current provided to said first and second biasing transistors as a function of the magnitude of sourcing/sinking current to/from, respectively, the load.

18. The amplifier as specified in claim 10 wherein said feedback circuitry is adapted to prevent crossover distortion at said amplifier output when said second output transistor sinks current from the load.
